(19) United States
(12) Patent Application Publication
(10) Pub. No.: US 2014/0329048 A1
(43) Pub. Date: Nov. 6, 2014

(54) COMPOSITE SHEET AND DISPLAY APPARATUS INCLUDING THE SAME

(71) Applicant: CHEIL INDUSTRIES INC., Gumi-si (KR)

(72) Inventors: Kyeong Taek Jung, Uiwang-si (KR); Jeong Ju Go, Uiwang-si (KR); Seung Beom Kee, Uiwang-si (KR); Won Jung Kim, Uiwang-si (KR); Jung Seob Kim, Uiwang-si (KR); Yong Wan Park, Uiwang-si (KR)

(73) Assignee: CHEIL INDUSTRIES INC., Gumi-si (KR)

(21) Appl. No.: 14/106,704

(22) Filed: Dec. 13, 2013

(30) Foreign Application Priority Data
Dec. 14, 2012 (KR) 10-2012-0146547

(51) Int. Cl. H01L 51/52; C08L 77/06; C08K 7/06; H01L 27/32; C08K 7/14

(52) U.S. Cl. CPC H01L 51/5253; H01L 27/3244; C08K 7/14; C08K 7/06; C08L 77/06; C08L 2205/16
USPC 428/113; 428/221; 442/59; 442/180; 442/1; 428/220

(57) ABSTRACT

A composite sheet includes a matrix impregnated with a fiber base. The fiber base includes first yarns and second yarns, and the second yarns intersect the first yarns at a constant angle. Each of the first and second yarns has an angle of greater than 0° to less than about 180° relative to a first direction of the matrix. A flexible display apparatus includes the composite sheet.

### CROSS-REFERENCE TO RELATED APPLICATION

This application claims priority to and the benefit of Korean Patent Application No. 10-2012-0146547, filed on Dec. 14, 2012 in the Korean Intellectual Property Office, the entire content of which is incorporated herein by reference.

### BACKGROUND

1. Technical Field

The present invention relates to a composite sheet and a display apparatus including the same.

2. Description of the Related Art

Substrate materials for display devices should be small, thin and light-weight as well as impact resistant and flexible. A flexible display substrate may be used in place of a glass substrate in a display apparatus.

Flexible display substrates exhibit good flexure resistance and thus have good applicability. However, continued research is being conducted into the application of flexible display substrates to foldable apparatuses. Although existing substrates for flexible displays have good flexure resistance, the existing substrates suffer from whitening or breakage due to the stress applied at the folded portion of the foldable apparatus.

In an attempt to solve this problem, and to protect the substrate, a protective film has been stacked on the surface of the substrate opposite to the surface of the substrate on which the device is stacked. A typical material of the protective film includes a matrix containing a silicone resin impregnated with glass fiber cloths, which makes the protective film applicable to flexible displays or other flexible materials. However, matrices impregnated with glass fiber cloths exhibit low elongation, and thus are difficult to apply on foldable apparatuses.

### SUMMARY

In accordance with an embodiment of the present invention, a composite sheet may include a matrix impregnated with a fiber base containing first yarns, and second yarns intersecting the first yarns at an angle. Each of the first and second yarns has an angle of greater than about 0° to less than about 180° relative to a first direction of the matrix.

In accordance with another embodiment of the present invention, a display apparatus may include: a substrate; an organic electroluminescent device on a first surface (or upper side) of the substrate; and a protective film on a second surface (or lower side) of the substrate, where the protective film includes the composite sheet according to an embodiment of the present invention.

### BRIEF DESCRIPTION OF THE DRAWINGS

The above and other aspects, features and advantages of the invention will become more apparent by reference to the following detailed description when considered in conjunction with the accompanying drawings, in which:

FIG. 1 is a conceptual diagram of a composite sheet according to an embodiment of the present invention;

FIG. 2 is an internal plan view of a composite sheet according to an embodiment of the present invention; and

FIG. 3 is a partial cross-sectional view of a flexible organic light emitting diode (OLED) apparatus according to an embodiment of the present invention.

### DETAILED DESCRIPTION

Embodiments of the present invention will be described with reference to the accompanying drawings. It should be understood by those of ordinary skill in the art that the present invention is not limited to the following embodiments and may be modified in different ways. In the drawings, elements that are not necessary for providing a description are omitted for clarity. Like components are denoted by like reference numerals throughout the specification. As used herein, ‘upper side (portion)’ and ‘lower side (portion)’ are defined as upper and lower based upon the depictions in the drawings, but can be used interchangeably.

According to embodiments of the invention, a composite sheet may include a matrix impregnated with a fiber base including first yarns, and second yarns intersecting the first yarns at an angle. Each of the first and second yarns has an angle of greater than about 0° to less than about 180° relative to a first direction of the matrix. The first direction of the matrix may be a longitudinal direction thereof, but is not limited thereto.

When each of the first and second yarns has an angle of greater than about 0° to less than about 180° relative to a first direction of the matrix, the composite sheet can exhibit good elongation in a longitudinal or width direction of the composite, and thus can be used as a protective film for a flexible display. In some embodiments, each of the first and second yarns may have an angle relative to the first direction of the matrix of about 10° to about 170°, for example about 10°, 20°, 30°, 40°, 50°, 60°, 70°, 80°, 90°, 100°, 110°, 120°, 130°, 140°, 150°, 160° or 170°. In other embodiments, each of the first and second yarns may have an angle relative to the first direction of the matrix of about 10° to about 80°, or about 100° to about 170°. Within any of these ranges, when included in the matrix, the first and second yarns can increase the elongation of the composite sheet in directions other than the longitudinal or width directions thereof. Each of the first and second yarns may include dozens or more fiber bundles formed of a suitable material, for example glass fiber bundles. The second yarns may intersect the first yarns at an angle of about 0° to about 90°.

The fiber base is a reinforcing material. In one embodiment, the fiber base may include a woven pattern in which the first and second yarns are woven at an angle therebetween. In another embodiment, the fiber base may include: a first layer which includes the first yarns; and a second layer on a first surface (or upper side) of the first layer and including the second yarns.

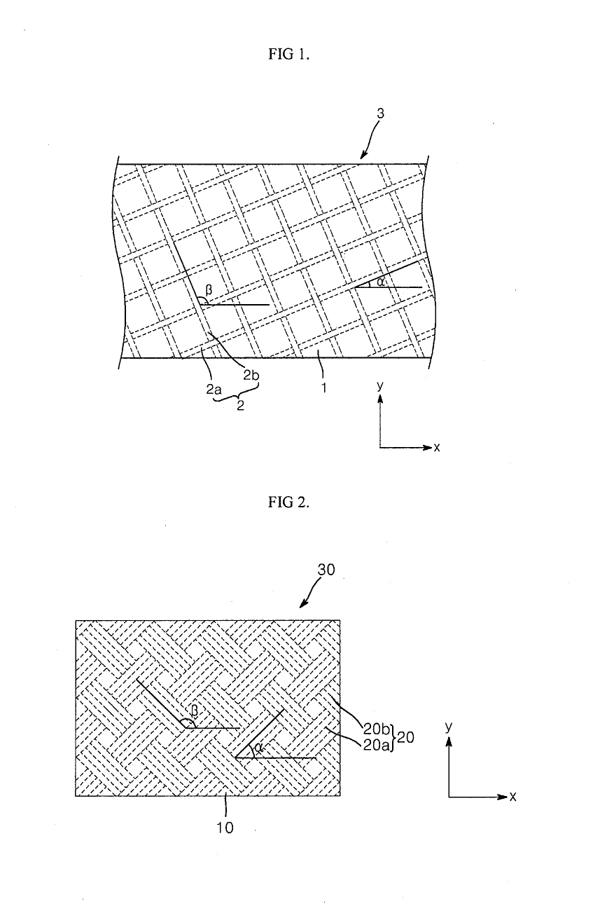

Hereinafter, a composite sheet according to an embodiment of the invention will be described with reference to FIGS. 1 and 2. FIG. 1 is a conceptual diagram of a composite sheet according to an embodiment of the present invention, and FIG. 2 is an internal plan view of the composite sheet of FIG. 1.

FIG. 1 is a conceptual diagram of a composite sheet according to an embodiment of the present invention. Referring to FIG. 1, a composite sheet 3 according to an embodiment of the invention may include a matrix 1 impregnated with a reinforcing material 2 of a fiber base in which first yarns 2a and second yarns 2b are woven. In the fiber base, an angle a between the first yarns 2a and a longitudinal direction of the matrix 1 may be greater than about 0° to less than about 180°, and an angle β between the second yarns 2b and the longitudinal direction of the matrix 1 may be greater than about 0° to less than about 180°. Within any of these ranges, when included in the matrix, the first and second yarns can increase the elongation of the composite sheet in directions other than the longitudinal and width directions thereof. In FIG. 1, the longitudinal direction of the matrix 1 (i.e., a first direction) is represented by the x-direction, the width direction thereof is represented by the y-direction, and the x and y-directions are orthogonal to each other.

In some embodiments, the first yarns 2a may have an angle of about 10° to about 80° relative to the longitudinal direction of the matrix 1, and the second yarns 2b may have an angle of about 100° to about 170° relative to the longitudinal direction thereof. Within either of these ranges, when included in the matrix, the first and second yarns can increase the elongation of the composite sheet in the longitudinal or width direction thereof.

Although the first and second yarns 2a, 2b are illustrated in FIG. 1 as being woven to intersect each other at 90°, the weave angle of the first and second yarns 2a, 2b is not limited thereto. As shown in FIG. 1, the first and second yarns are woven with each other, and may be woven in a plain weave, twill weave, or the like.

FIG. 2 is an internal plan view of a composite sheet according to an embodiment of the invention. Referring to FIG. 2, a composite sheet 30 may include a matrix 10 impregnated with a reinforcing material 20 of a fiber base in which first yarns 20a and second yarns 20b are woven. In the fiber base, an angle a between the first yarns 20a and a longitudinal direction of the matrix 10 may be greater than about 0° to less than about 180°, and an angle β between the second yarns 20b and the longitudinal direction of the matrix 10 may be greater than about 0° to less than about 180°. Within either of these ranges, when included in the matrix, the first and second yarns can increase the elongation of the composite sheet in directions other than the longitudinal and width directions thereof.

In FIG. 2, the longitudinal direction of the matrix 10 (i.e., a first direction) is represented by the x-direction, the width direction thereof is represented by the y-direction, and the x and y directions are orthogonal to each other.

As the fiber base, any base capable of realizing properties such as flexibility, flexure resistance, and the like may be used without limitation. For example, the fiber base may include a substrate of glass materials or polymeric materials. In some embodiments, for example, the fiber base may include glass fiber cloths, glass fabrics, nonwoven glass fabrics, glass fiber meshes, carbon fiber composites, carbon fibers, Kevlar fibers, aramid fibers, and combinations thereof.

As the matrix, any suitable matrix material may be used without limitation as long as the matrix can be applied to flexible displays or other flexible materials, provide transparency after lamination or curing, and realize desirable properties such as flexibility, flexure resistance, and the like. For example, the matrix may include silicone resins, acrylic resins, polysiloxane-polycarbonate copolymer resins, polycarbonate resins, polysiloxane resins, polyester resins (such as polyethylene terephthalate resins, polyethylene naphthalate resins or the like), polyethersulfone resins, polyarylate resins, and polyimide resins.

In some embodiments, for example, the matrix may be a silicone resin, and the silicone resin may include a repeating unit represented by Formula 1.

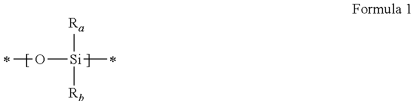

In Formula 1, * is a bonding site; and Rₐ and R_{b} are each independently a hydrogen atom, a C₁ to C₂₀ alkyl group, a C₂ to C₂₀ alkenyl group, a C₂ to C₂₀ alkynyl group, a C₁ to C20 alkoxy group, a C₃ to C₃₀ cycloalkyl group, a C₃ to C₃₀ cycloalkenyl group, a C₃ to C₃₀ cycloalkynyl group, a C₆ to C₃₀ aryl group, or a C₆ to C₃₀ aryloxy group.

In some embodiments, for example, the silicone resin may be a linear or cyclic silicone resin including the repeating unit represented by Formula 1. When the silicone resin is a linear silicone resin, the silicone resin may include terminal groups represented by Formulae 1a and 1b.

R₁R₂R₃SiO-* Formula 1a

R₄R₅R₆Si-* Formula 1b

In Formula 1a and 1b, * is a bonding site; and R₁, R₂, R₃, R₄, R₅ and R₆ are each independently a hydrogen atom, a C₁ to C₂₀ alkyl group, a C₂ to C₂₀ alkenyl group, a C₂ to C₂₀ alkynyl group, a C₁ to C₂₀ alkoxy group, a C₃ to C₃₀ cycloalkyl group, a C₃ to C₃₀ cycloalkenyl group, a C₃ to C₃₀ cycloalkynyl group, a C₆ to C₃₀ aryl group, a C₆ to C₃₀ aryloxy group, or a UV curable functional group.

In some embodiments, the UV curable functional group may be a vinyl group, or a (meth)acrylate group.

The composite sheet may include about 40% by weight (wt %) to about 90 wt %, for example about 40 wt %, 50 wt %, 60 wt %, 70 wt %, 80 wt % or 90 wt % of the matrix, and about 10 wt % to about 60 wt %, for example about 10 wt %, 20 wt %, 30 wt %, 40 wt %, 50 wt % or 60 wt % of the fiber base. Within either of these ranges, the composite sheet can be applied to flexible displays, substrates or protective films, and has increased elongation.

The composite sheet according to embodiments of the present invention exhibits good transparency, flexure resistance, flexibility, and the like, and thus may be used as a protective film for flexible displays. For this purpose, the composite sheet may have a thickness of about 0.1 μm to about 5 mm. In addition, the composite sheet may be used as a protective film (e.g., a lower protective film) that contacts the substrate (or the like) to protect the substrate (or the like).

The composite sheet may have an elongation of about 105% to about 130%, as measured in accordance with ASTM D638. Within this range, the composite sheet can be used to stack a device or the like on the substrate due to the improved elongation in the longitudinal or width direction thereof. As a result, the composite sheet can be used as a protective film of a flexible display apparatus.

The composite sheet may have a coefficient of thermal expansion of about 0 ppm/° C. to about 400 ppm/° C., for example about 0 ppm/° C. to about 10 ppm/° C., or about 3 ppm/° C. to about 7 ppm/° C., as measured in accordance with ASTM E 831. Within any of these ranges, when the composite sheet is used as a material for a protective film, a substrate or the like, thermal deformation thereof can be suppressed.

The composite sheet may be used as a protective film on a liquid crystal display device substrate, a flexible substrate, an organic EL display device substrate, a color filter substrate, a solar cell substrate, or the like. In addition, the composite sheet may also be used in a transparent sheet, optical lens, optical device, OLED encapsulation material, cover glass, display multilayer thin film, or the like.

According to embodiments of the present invention, the composite sheet may exhibit good elongation, and may have a low coefficient of thermal expansion in a certain direction. As a result, the composite sheet can be used as a protective film (e.g., a lower protective film) in a foldable flexible display apparatus. When a device is stacked on one side of the substrate, the protective film may include a film on the other side thereof to protect the substrate.

The composite sheet may be prepared by impregnating a reinforcing material with a matrix composition, followed by removing excess matrix composition (by, for example, squeezing out the excess composition in contact with the lower and/or upper surfaces of the reinforcing material), and then curing the resulting material.

In one embodiment, a flexible display apparatus may include the composite sheet according to embodiments of the invention. For example, the flexible display apparatus may include: a substrate; an organic electroluminescent device on a first surface (e.g., an upper side) of the substrate; and a protective film on a second surface (e.g., a lower side) of the substrate. The protective film may include the composite sheet according to an embodiment of the invention.

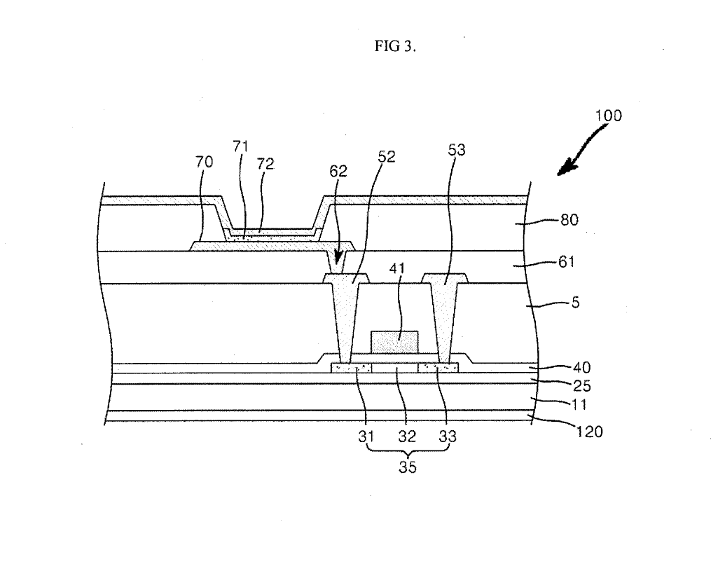

Hereinafter, a flexible display apparatus according to embodiments of the present invention will be described with reference to FIG. 3, which is a partial cross-sectional view of an OLED display apparatus according to an embodiment of the present invention. Referring to FIG. 3, a display apparatus 100 may include: a substrate 110; a protective film 120 on a second surface (e.g., the lower side, as shown in FIG. 3) of the substrate 110; a buffer layer 25 on a first surface (e.g., the upper side, as shown in FIG. 3) of the substrate 110; a gate electrode 41 on the buffer layer 25; and a gate insulating layer 40 between the gate electrode 41 and the buffer layer 25. An active layer 35 including source and drain regions 31, 32, 33 is formed in the gate insulating layer 40. An interlayer insulating layer 5 (through which source and drain electrodes 52, 53 are formed) is formed on the gate insulating layer 40. A passivation layer 61 (including a contact hole 62), a first electrode 70 and a pixel definition layer 80 are formed on the interlayer insulating layer 5. An organic light emitting layer 71 and a second electrode 72 are formed on the pixel definition layer 80. The protective film 120 may include a composite sheet according to an embodiment of the invention, and the substrate 110 may be a flexible substrate.

The present invention will now be described with reference to the following examples. However, it should be noted that these examples are provided for illustration only and are not to be construed in any way as limiting the present invention.

### EXAMPLE 1

A glass fiber cloth (#3313, Nittobo CO., Ltd.) including glass fiber bundles having weft threads and warp threads intersecting each other at 90° was impregnated in an impregnation tank containing a silicone resin (Sylgard 184, MH series, XD series, Dow Corning Co., Ltd.). After impregnation, the glass fiber cloth was passed through a squeezing member and then cured, thereby preparing a composite sheet having an internal plan view like that shown in FIG. 2. The composite sheet was attached to a device such that the weft threads were arranged at 45° relative to a longitudinal direction of the matrix of the composite sheet, thereby forming a lower protective film.

### COMPARATIVE EXAMPLE 1

A composite sheet was prepared as in Example 1 except that the weft threads were arranged at 90° relative to the longitudinal direction of the matrix.

### COMPARATIVE EXAMPLE 2

A composite sheet was prepared as in Example 1 except that an epoxy resin was used instead of the silicone resin as the matrix composition.

The composite sheets of Example and Comparative Examples were evaluated as to the following properties.

1) Angle: The angle of the weft or warp threads relative to the longitudinal direction of the matrix was measured.

2) Elongation: Elongation was measured using an Instron device (LX, SATEC Co., Ltd.) in accordance with ASTM D638.

3) Flexure resistance: Flexure resistance was measured by a mandrel bend test in accordance with ASTM D522-93a using various rod diameters. A rod having a constant diameter was used and the number of measurements was 100,000. Finally, flexure resistance was determined based on whether whitening of the film occurred.

4) Recovery rate after deformation: When the composite sheet was unfolded after being folded at the middle thereof for 30 minutes, the rate at which the composite sheet recovered a planar shape was evaluated.

TABLE 1

| | | | | | Recovery rate |
|---|---|---|---|---|---|
| | | | | Flexure | after |
| | Matrix | Angle | Elongation | resistance | deformation |
| | material | (°) | (%) | (ø) | (%) |
| Example 1 | Silicone | 45 | 130 | 3 mm | 99 |
| Comparative | Silicone | 90 | 100 | 5 mm | 98 |
| Example 1 | | | | | |
| Comparative | Epoxy | 45 | 102 | 10 mm | 0 |
| Example 2 | | | | | |

As shown in Table 1, the composite sheet according to embodiments of the invention exhibits good flexure resistance and elongation, and thus can be used as a protective film of a flexible display apparatus. For example, the composite sheet according to embodiments of the invention exhibits improved flexure resistance, flexibility and elongation by disposing a fiber base containing first and second yarns at a specific angle relative to the longitudinal direction of the matrix. Also, the composite sheet according to embodiments of the invention exhibit good water vapor permeability, transmittance and coefficient of thermal expansion.

Conversely, the composite sheet of Comparative Example 1 (in which the weft threads were arranged at 90° relative to the longitudinal direction of the matrix) exhibited lower elongation than the composite sheet according to embodiments of the invention, and thus could not realize the improvements associated with embodiments of the present invention. In addition, the composite sheet of Comparative Example 2 (in which an epoxy resin was used instead of the silicon resin) did not show improved flexure resistance or recovery rate after deformation even though it had angles of 45° and 90°, and thus could not be used as a lower protective film of the flexible display apparatus.

Although some exemplary embodiments have been disclosed herein, it should be understood by those of ordinary skill in the art that various modifications, changes, and alterations can be made to the described embodiments without departing from the spirit and scope of the invention, as defined in the attached claims.

What is claimed is:

1. A composite sheet comprising:
a matrix impregnated with a fiber base, the fiber base comprising first yarns and second yarns, the second yarns intersecting the first yarns at an angle,
each of the first and second yarns having an angle of greater than about 0° to less than about 180° relative to a first direction of the matrix.

2. The composite sheet according to claim 1, wherein each of the first and second yarns has an angle of about 10° to about 170° relative to the first direction of the matrix.

3. The composite sheet according to claim 1, wherein the angle at which the second yarns intersect the first yarns is greater than 0° to about 90°.

4. The composite sheet according to claim 1, wherein the angle at which the second yarns intersect the first yarns is about 90°.

5. The composite sheet according to claim 1, wherein the composite sheet has a weave pattern in which the first and second yarns are woven with each other.

6. The composite sheet according to claim 1, comprising:
a first layer comprising the first yarns; and
a second layer on the first layer, the second layer comprising the second yarns.

7. The composite sheet according to claim 1, wherein the fiber base comprises a material selected from the group consisting of glass fiber cloths, glass fabrics, nonwoven glass fabrics, glass fiber meshes, carbon fiber composites, carbon fibers, Kevlar fibers, aramid fiber, and combinations thereof.

8. The composite sheet according to claim 1, wherein the matrix comprises a material selected from the group consisting of silicone resins, acrylic resins, polysiloxane-polycarbonate copolymer resins, polycarbonate resins, polysiloxane resins, polyester resins, polyethersulfone resins, polyarylate resins, polyimide resins, and combinations thereof.

9. The composite sheet according to claim 1, wherein the composite sheet has an elongation of about 105% to about 130%.

10. The composite sheet according to claim 1, wherein the composite sheet has a thickness of about 0.1 μm to about 5 mm.

11. The composite sheet according to claim 1, wherein the matrix is present in an amount of about 40 wt % to about 90 wt %, and the fiber base is present in an amount of about 10 wt % to about 60 wt %.

12. A flexible display apparatus comprising:
a substrate;
an organic electroluminescent device on a first surface of the substrate; and
a protective film on a second surface of the substrate, the protective film comprising the composite sheet according to claim 1.
